(19) United States
(12) Patent Application Publication
(10) Pub. No.: US 2024/0038755 A1
(43) Pub. Date: Feb. 1, 2024

(54) SEMICONDUCTOR STRUCTURE OF CELL ARRAY

(71) Applicant: MEDIATEK INC., Hsinchu City (TW)

(72) Inventors: Chia-Hsin HU, Hsinchu City (TW); Wei-Chieh TSENG, Hsinchu City (TW); Zheng ZENG, Hsinchu City (TW)

(21) Appl. No.: 18/344,126

(22) Filed: Jun. 29, 2023

Related U.S. Application Data
(60) Provisional application No. 63/369,981, filed on Aug. 1, 2022.

(51) Int. Cl. H01L 27/02; H01L 29/78; H01L 27/092

(52) U.S. Cl. CPC H01L 27/0207; H01L 29/785; H01L 27/0924; H01L 27/0922; H01L 29/66545

(57) ABSTRACT

A semiconductor structure is provided. The semiconductor structure includes a logic cell. The logic cell includes a first transistor and a second transistor. The first transistor includes a first gate structure extending in a first direction and overlapping a first semiconductor fin. The second transistor includes a second gate structure extending in the first direction and overlapping the first semiconductor fin and a second semiconductor fin. The first and second semiconductor fins extend in a second direction that is perpendicular to the first direction. The first and second transistors share a source/drain region, and one end of the first gate structure is formed between the first and second semiconductor fins.

### CROSS REFERENCE TO RELATED APPLICATIONS

This application claims the benefit of U.S. Provisional Application No. 63/369,981, filed Aug. 1, 2022, the entirety of which is incorporated by reference herein.

### BACKGROUND OF THE INVENTION

### Field of the Invention

The present invention relates to a cell array, and, in particular, to semiconductor structure of a cell array.

### Description of the Related Art

Integrated circuits (ICs) have become increasingly important. Applications using ICs are used by millions of people. These applications include cell phones, smartphones, tablets, laptops, notebook computers, PDAs, wireless email terminals, MP3 audio and video players, portable wireless web browsers, and so on. Integrated circuits increasingly include powerful and efficient on-board data storage and logic circuitry for signal control and processing.

As down-scaling of integrated circuits has increased, they have become more compact. When the number of standard cells (frequently used in integrated circuits) is increased, this increases the chip area. Therefore, a cell array for power and speed is desired.

### BRIEF SUMMARY OF THE INVENTION

An embodiment of the present invention provides a semiconductor structure. The semiconductor structure includes a logic cell. The logic cell includes a first transistor and a second transistor. The first transistor includes a first gate structure extending in a first direction and overlapping a first semiconductor fin. The second transistor includes a second gate structure extending in the first direction and overlapping the first semiconductor fin and a second semiconductor fin. The first and second semiconductor fins extend in a second direction that is perpendicular to the first direction. The first and second transistors share a source/drain region, and one end of the first gate structure is formed between the first and second semiconductor fins.

Moreover, an embodiment of the present invention provides a semiconductor structure. The semiconductor structure includes a cell array. The cell array includes a plurality of first logic cells. P-type transistors of the first logic cells disposed in a first row of the cell array share a plurality of first continuous fins, and N-type transistors of the first logic cells disposed in the first row of the cell array share a plurality of second continuous fins. The number of first continuous fins is different from the number of second continuous fins in the first row of the cell array.

Furthermore, an embodiment of the present invention provides a semiconductor structure. A plurality of logic cells are formed in a cell array. P-type transistors of the logic cells disposed in a first row of the cell array share a plurality of first semiconductor fins extending in a first direction, and N-type transistors of the logic cells disposed in the first row of the cell array share a plurality of second semiconductor fins extending in the first direction. A first logic cell in the first row of the cell array includes a first P-type transistor and a first N-type transistor. The number of first semiconductor fins overlapping the first gate structure of the first P-type transistor is different from the number of second semiconductor fins overlapping a second gate structure of the first N-type transistor. The first and second gate structures extending in a second direction that is perpendicular to the first direction, and the first and second gate structures are aligned in the second direction.

### BRIEF DESCRIPTION OF THE DRAWINGS

The present invention can be more fully understood by reading the subsequent detailed description and examples with references made to the accompanying drawings, wherein:

FIG. 1 shows a simplified diagram illustrating a cell array of an IC according to some embodiments of the invention.

FIG. 2 shows a simplified layout illustrating the logic cells in a row of the cell array of FIG. 1 according to some embodiments of the invention.

FIG. 3A shows a cross-sectional view of the semiconductor structure of the logic cell along line A-A′ of FIG. 2 according to some embodiments of the invention.

FIG. 3B shows a cross-sectional view of the semiconductor structure of the logic cell along line B-B′ of FIG. 2 according to some embodiments of the invention.

FIG. 3C shows a cross-sectional view of the semiconductor structure of the logic cell along line C-C′ of FIG. 2 according to some embodiments of the invention.

FIG. 3D shows a cross-sectional view of the semiconductor structure of the logic cell along line D-D′ of FIG. 2 according to some embodiments of the invention.

FIG. 3E shows a cross-sectional view of the semiconductor structure of the logic cell along line E-E′ of FIG. 2 according to some embodiments of the invention.

FIG. 4 shows a simplified layout illustrating the logic cell in a row of the cell array of FIG. 1 according to some embodiments of the invention.

FIG. 5A shows a cross-sectional view of the semiconductor structure of the logic cell along line F-F′ of FIG. 4 according to some embodiments of the invention.

FIG. 5B shows a cross-sectional view of the semiconductor structure of the logic cell along line G-G′ of FIG. 4 according to some embodiments of the invention.

FIG. 6 shows a simplified layout illustrating a logic cell in a row of the cell array of FIG. 1 according to some embodiments of the invention.

FIG. 7 shows a simplified layout illustrating a logic cell in a row of the cell array of FIG. 1 according to some embodiments of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

Some variations of the embodiments are described. Throughout the various views and illustrative embodiments, like reference numbers are used to designate like elements. It should be understood that additional operations can be provided before, during, and/or after a disclosed method, and some of the operations described can be replaced or eliminated for other embodiments of the method.

Furthermore, spatially relative terms, such as “beneath,” “below,” “lower,” “above,” “upper” and the like, may be used herein for ease of description to describe one element or feature's relationship to another element(s) or feature(s) as illustrated in the figures.

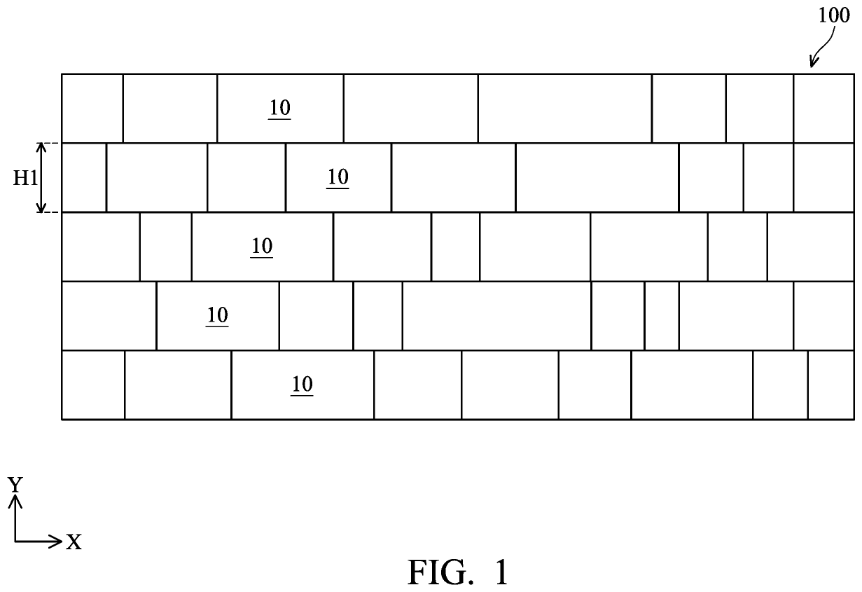

FIG. 1 shows a simplified diagram illustrating a cell array 100 of an IC according to some embodiments of the invention. The cell array 100 is formed by multiple logic cells 10. The logic cells 10 are standard cells (e.g., INV (inverter), AND, OR, NAND, NOR, Flip-Flop, SCAN, etc.), or a combination of standard cells, or specific logic functional cells. Furthermore, the logic functions of the logic cells 10 may be the same or different. Moreover, each logic cell 10 includes multiple transistors.

In FIG. 1, the logic cells 10 in the same row have the same cell height H1 (e.g., in the Y-direction) in the layout. The logic cells 10 corresponding to the same function or operation may have the same circuit configuration with different semiconductor structures and/or different layouts. Furthermore, the logic cells 10 may have the same or different cell widths (e.g., in X-direction) in the layout. It should be noted that the number and the configuration of the logic cells 10 in the cell array 100 are used as an example, and not to limit the invention.

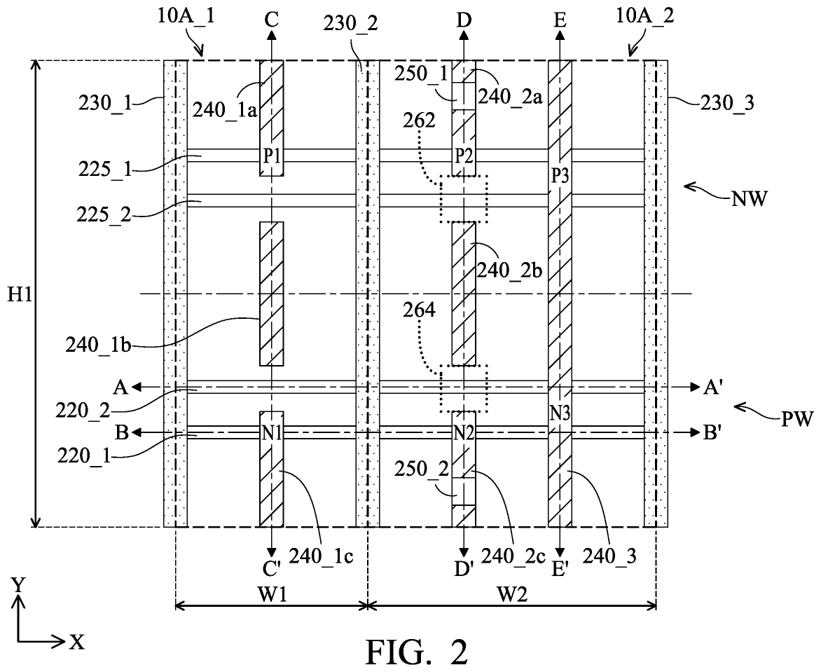

FIG. 2 shows a simplified layout illustrating the logic cells 10A_1 and 10A_2 in a row of the cell array 100 of FIG. 1 according to some embodiments of the invention. The logic cells 10A_1 and 10A_2 are arranged between a power line (not shown) and a ground line (not shown). The logic cell 10A_1 has a cell height H1 and a cell weight W1, and the logic cell 10A_2 has a cell height H1 and a cell weight W2. Furthermore, the outer boundaries of the logic cells 10A_1 and 10A_2 are illustrated using dashed lines.

In the logic cells 10A_1 and 10A_2, two fins 225_1 and 225_2 extend in the X-direction over an N-type well region NW, and two semiconductor fins 220_1 and 220_2 extend in the X-direction over a P-type well region PW. In some embodiments, the semiconductor fins 220_1 and 220_2 and the semiconductor fins 225_1 and 225_2 are continuous fins in the row of the cell array 100, e.g., the semiconductor fins in each row of the cell array 100 are continuous and have the same length. In other words, the logic cells in the sane row share the semiconductor fins.

In FIG. 2, the logic cell 10A_1 includes a P-type transistor P1 over the N-type well region NW and an N-type transistor N1 over the P-type well region PW. The P-type transistor P1 and the N-type transistor N1 are configured to perform a specific logic function for the logic cell 10A_1, such as an inverter. It should be noted that the number of transistors in the logic cell 10A_1 is used as an example, and not to limit the disclosure. The logic cell 10A_1 may include more P-type transistors and more N-type transistors to perform a specific function.

In the logic cell 10A_1, a gate structure 240_1a extending in the Y-direction forms the P-type transistor P1 with an underlying active region formed by the semiconductor fin 225_1. Moreover, a gate structure 240_1c extending in the Y-direction forms the N-type transistor N1 with an underlying active region formed by the semiconductor fin 220_1. In other words, the gate structure 240_1a does not overlap the semiconductor fin 225_2, and the gate structure 240_1c does not overlap the semiconductor fin 220_2. Therefore, the P-type transistor P1 and the N-type transistor N1 are single fin transistors. In order to simplify, detail of the gate structures in FIG. 2, such as the gate dielectric, the gate electrode, the space and so on, and corresponding source/drain regions, will be omitted.

In the logic cell 10A_1, the gate structures 240_1a, 240_1b and 240_1c are aligned in the Y-direction, i.e., the gate structures 240_1a, 240_1b and 240_1c are arranged on the same line. The gate structure 240_1b is disposed between the semiconductor fins 220_2 and 225_2 and across an interface between the N-type well region NW and the P-type well region PW. One end of the gate structure 240_1a is formed between the semiconductor fins 225_1 and 225_2, and one end of the gate structure 240_1c is formed between the semiconductor fins 220_1 and 220_2. In some embodiments, the gate structures 240_1a and 240_1b have natural ends on opposite sides of the semiconductor fin 225_2, and the gate structures 240_1b and 240_1c have natural ends on opposite sides of the semiconductor fin 220_2. In the logic cell 10A_1, the gate structures have the symmetry layout configuration, e.g., the gate structure layout is mirrored along the interface between the N-type well region NW and the P-type well region PW.

In some embodiments, the gate structures 240_1a, 240_1b and 240_1c are formed by the replacement metal gate (RMG) process. The replacement metal gate process is performed to create a sacrificial or dummy gate during fabrication, and then later replacing the dummy gate with a metal gate structure. In other words, the sacrificial or dummy gate between the gate structures 240_1a and 240_1b and the sacrificial or dummy gate between the gate structures 240_1b and 240_1c are not been replaced. Furthermore, the gate structure 240_1a is electrically connected to the gate structure 240_1c through the interconnect structure over the logic cell 10A_1. For example, a control signal is applied to the gate structures 240_1a and 240_1c through the interconnect structure. In some embodiments, no signal is applied to the gate structures 240_1b.

In the logic cell 10A_1, the non-active dummy gates 230_1 and 230_2 extending in the Y-direction are dummy gates. The gate structures 240_1a through 240_1c are arranged between the non-active dummy gates 230_1 and 230_2, and the N-type transistor N1 and the P-type transistor P1 are surrounded by the non-active dummy gates 230_1 and 230_2. In other words, the non-active dummy gates 230_1 and 230_2 are arranged in the boundary of the logic cell 10A_1.

In FIG. 2, the logic cell 10A_2 includes the P-type transistors P2 and P3 over the N-type well region NW and the N-type transistors N2 and N3 over the P-type well region PW. The P-type transistors P2 and P3 and the N-type transistors N2 and N3 are configured to perform a specific logic function for the logic cell 10A_2. It should be noted that the number of transistors in the logic cell 10A_2 is used as an example, and not to limit the disclosure. The logic cell 10A_2 may include more or fewer P-type transistors and more or fewer N-type transistors to perform a specific function.

In the logic cell 10A_2, a gate structure 240_2a extending in the Y-direction forms the P-type transistor P2 with an underlying active region formed by the semiconductor fin 225_1. A gate structure 240_3 extending in the Y-direction forms the P-type transistor P3 with an underlying active region formed by the semiconductor fins 225_1 and 225_2. Moreover, a gate structure 240_2c extending in the Y-direction forms the N-type transistor N2 with an underlying active region formed by the semiconductor fin 220_1. The gate structure 240_3 extending in the Y-direction forms the N-type transistor N3 with an underlying active region formed by the semiconductor fins 220_1 and 220_2. In other words, the gate structure 240_2a does not overlap the semiconductor fin 225_2, and gate structure 240_2c does not overlap the semiconductor fin 220_2. Therefore, the P-type transistor P2 and the N-type transistor N2 are single fin transistors, and the P-type transistor P3 and the N-type transistor N3 are dual-fin transistors.

In the logic cell 10A_2, the gate structures 240_2a, 240_2b and 240_2c are aligned in the Y-direction, i.e., the gate structures 240_2a, 240_2b and 240_2c are arranged on the same line. The gate structure 240_2b is disposed between the semiconductor fins 220_2 and 225_2 and across the interface between the N-type well region NW and the P-type well region PW. One end of the gate structure 240_2a is formed between the semiconductor fins 225_1 and 225_2, and one end of the gate structure 240_2c is formed between the semiconductor fins 220_1 and 220_2. In some embodiments, the gate structures 240_2a, 240_2b and 240_2c are formed by performing the cut metal gate (CMG) process on a gate structure. For example, after a metal gate replaces a dummy gate structure (e.g., a polysilicon gate), the metal gate structure is cut (e.g., by an etching process), label as 262 and 264, to separate the metal gate structure into three gate segments, i.e., the gate structures 240_2a, 240_2b and 240_2c. The gate structure 240_3 extends in the Y direction. The P-type transistor P3 and the N-type transistor N3 share the same gate structure 240_3. In other words, the gate structure 240_3 overlaps the semiconductor fins 220_1 and 220_2 and the semiconductor fins 225_1 and 225_2. In the logic cell 10A_2, the gate structures have the symmetry layout configuration, e.g., the gate structure layout is mirrored along the interface between the N-type well region NW and the P-type well region PW.

In the logic cell 10A_2, the non-active dummy gates 230_2 and 230_3 extending in the Y-direction are dummy gates. The gate structures 240_2a through 240_2c and the gate structure 240_3 are arranged between the non-active dummy gates 230_2 and 230_3, and the N-type transistors N2 and N3 and the P-type transistor P2 and P3 are surrounded by the non-active dummy gates 230_2 and 230_3. In other words, the non-active dummy gates 230_2 and 230_3 are arranged in the boundary of the logic cell 10A_2. Moreover, the signals are applied to the gate structures 240_2a and 240_2c through the interconnect structures (e.g., the interconnect features 250_1 and 250_2) over the logic cell 10A_2. In some embodiments, no signal is applied to the gate structures 240_2b.

As shown in FIG. 2, the logic cell with the single-fin transistors and the logic cell with the multi-fin transistors are arranged in the same row of the cell array 100. Furthermore, the single-fin transistors and the multi-fin transistors are arranged in the same logic cell (e.g., the logic cell 10A_2). In some embodiments, the transistors in the same logic cell have the same number of semiconductor fins. In some embodiments, the transistors in the same logic cell have the different number of semiconductor fins. The multi-fin transistors are used for performance (e.g., speed), and the single-fin transistors are used for low power and low leakage. Therefore, compared with the traditional performance cell array formed by the logic cells with the multi-fin transistors or the traditional low power cell array formed by the logic cells with the single-fin transistors, the logic cell 100 is capable of satisfying low power and high-performance (off-state leakage current requirements).

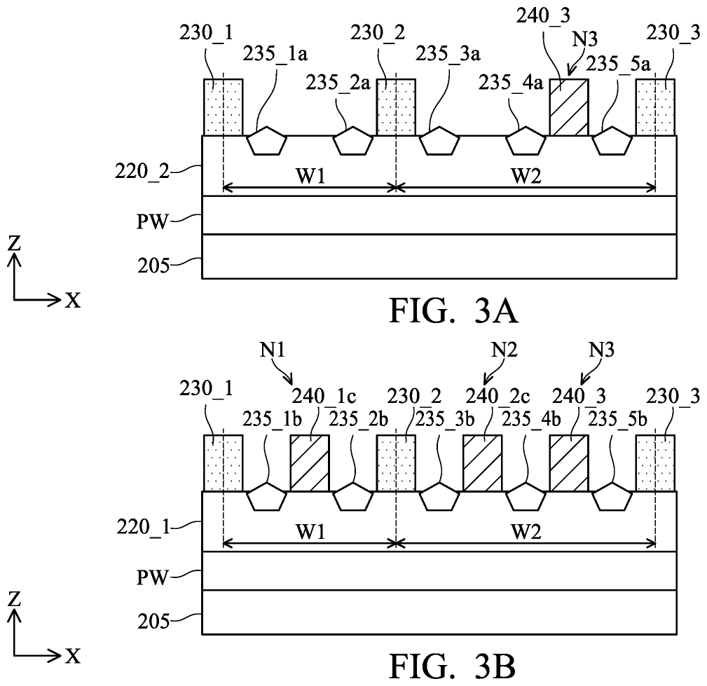

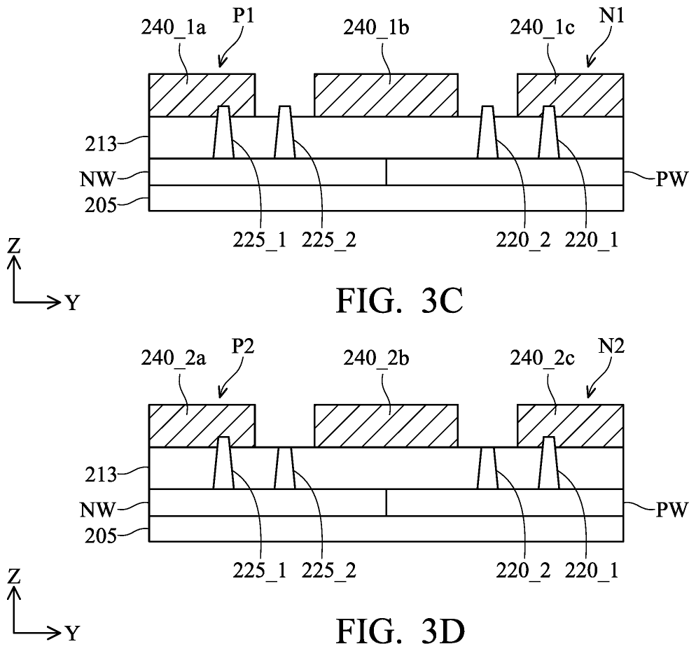

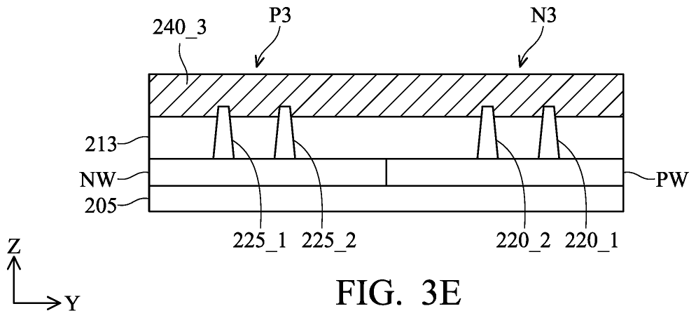

FIG. 3A shows a cross-sectional view of the semiconductor structure of the logic cell along line A-A′ of FIG. 2 according to some embodiments of the invention. The P-type well region PW is formed over a semiconductor substrate 205. In some embodiments, the semiconductor substrate 205 is a Si substrate. In some embodiments, the material of the semiconductor substrate 205 is selected from a group consisting of bulk-Si, SiP, SiGe, SiC, SiPC, Ge, SOI-Si, SOI-SiGe, III-VI material, or a combination thereof.

The semiconductor fin 220_2 extending in the X-direction is formed over the P-type well region PW. The non-active dummy gates 230_1 through 230_3 are formed over the semiconductor fin 220_2. As described above, the non-active dummy gates 230_1 and 230_2 are arranged in the boundary of the logic cell 10A_1, and the non-active dummy gates 230_2 and 230_3 are arranged in the boundary of the logic cell 10A_2.

The source/drain features 235_1a through 235_5a are formed over the semiconductor fin 220_2. In some embodiments, the source/drain features 235_1a through 235_5a are formed by the epitaxially-grown material. In some embodiments, for an N-type transistor, the epitaxially-grown materials may include SiP, SiC, SiPC, SiAs, Si, or a combination thereof. In some embodiments, for a P-type transistor, the epitaxially-grown materials may include SiGe, SiGeC, Ge, Si, a boron-doped SiGe, boron and carbon doped SiGe, or a combination thereof.

In FIG. 3A, the non-active dummy gate 230_2 is formed between the source/drain features 235_2a and 235_3a, and the non-active dummy gate 230_2 is shared by the logic cells 10A_1 and 10A_2. Furthermore, the gate structure 240_3 is formed between the source/drain features 235_4a and 235_5a. In other words, the source/drain features 235_4a and 235_5a on opposite sides of the gate structure 240_3 serve as the source region and the drain region of the N-type transistor N3. It should be noted that no gate structure is formed between the source/drain features 235_1a and 235_2a, and no gate structure is formed between the source/drain features 235_3a and 235_4a.

FIG. 3B shows a cross-sectional view of the semiconductor structure of the logic cell along line B-B′ of FIG. 2 according to some embodiments of the invention. The semiconductor fin 220_1 extending in the X-direction is formed over the P-type well region NW. The non-active dummy gates 230_1 through 230_3 are formed over the semiconductor fin 220_1. The source/drain features 235_1b through 235_5b are formed over the semiconductor fin 220_1. Similarly, the source/drain features 235_1b through 235_5b are formed by the epitaxially-grown material.

In FIG. 3B, the non-active dummy gate 230_2 is formed between the source/drain features 235_2b and 235_3b, and the non-active dummy gate 230_2 is shared by the logic cells 10A_1 and 10A_2. Furthermore, the gate structure 240_1c is formed between the source/drain features 235_1b and 235_2b. In other words, the source/drain features 235_1b and 235_2b on opposite sides of the gate structure 240_1c serve as the source region and the drain region of the N-type transistor N1. The gate structure 240_2c is formed between the source/drain features 235_3b and 235_4b. In other words, the source/drain features 235_3b and 235_4b on opposite sides of the gate structure 240_2c serve as the source region and the drain region of the N-type transistor N2. The gate structure 240_3 is formed between the source/drain features 235_4b and 235_5b. In other words, the source/drain features 235_4b and 235_5b on opposite sides of the gate structure 240_3 serve as the source region and the drain region of the N-type transistor N3. The N-type transistors N2 and N3 share a source/drain region (i.e., the source/drain feature 235_4b).

In some embodiments, the source/drain feature 235_1b of FIG. 3B is electrically connected to the source/drain feature 235_1a of FIG. 3A through a connect feature (not shown), such as a longer contact. Similarly, the source/drain features 235_2b, 235_3b, 235_4b and 235_5b of FIG. 3B are electrically connected to the source/drain features 235_2a, 235_3a, 235_4a and 235_5a through individual connect features (not shown), respectively.

FIG. 3C shows a cross-sectional view of the semiconductor structure of the logic cell along line C-C′ of FIG. 2 according to some embodiments of the invention. The N-type well region NW and the P-type well region PW are formed over a semiconductor substrate 205. The semiconductor fins 225_1 and 225_2 are formed over the N-type well region NW, and the semiconductor fins 220_1 and 220_2 are formed over the P-type well region PW. The semiconductor fins 220_1 and 220_2 and the semiconductor fins 225_1 and 225_2 are separated from each other by the shallow trench isolation (STI) 213.

The gate structure 240_1a extends in the Y-direction and overlaps the semiconductor fin 225_1 to form the P-type transistor P1 , i.e., the P-type transistor P1 is a single fin transistor. The gate structure 240_1b extends in the Y-direction and overlaps the interface between the N-type well region NW and the P-type well region PW. The gate structure 240_1c extends in the Y-direction and overlaps the semiconductor fin 220_1 to form the N-type transistor N1, i.e., the N-type transistor N1 is a single fin transistor. The gate structure 240_1a is separated from the gate structure 240_1b, and the gate structure 240_1b is separated from the gate structure 240_1c. In some embodiments, the gate structure 240_1b is separated from the gate structures 240_1a and 240_1c by the sacrificial or dummy gate (not shown) that have not been replaced with the metal gate structure.

It should be noted that among two adjacent semiconductor fins (e.g., the semiconductor fins 225_1 and 225_2 or the semiconductor fins 220_1 and 220_2) in FIG. 3C, only single semiconductor fin is covered by the gate structure. For example, the semiconductor fin 225_1 is covered by the gate structure 240_1a, and the semiconductor fin 220_1 is covered by the gate structure 240_1c. Furthermore, the semiconductor fin 225_1 overlapping the gate structure 240_1a is separated from the semiconductor fin 220_1 overlapping the gate structure 240_1c by the semiconductor fins 225_2 and 220_2 not overlapping any gate structure. In other words, the semiconductor fins 225_2 and 220_2 close to the interface between the P-type well region PW and the N-type well region are not covered by the gate structure.

FIG. 3D shows a cross-sectional view of the semiconductor structure of the logic cell along line D-D′ of FIG. 2 according to some embodiments of the invention. The gate structure 240_2a extends in the Y-direction and overlaps the semiconductor fin 225_1 to form the P-type transistor P2, i.e., the P-type transistor P2 is a single fin transistor. The gate structure 240_2b extends in the Y-direction and overlaps the interface between the N-type well region NW and the P-type well region PW. The gate structure 240_2c extends in the Y-direction and overlaps the semiconductor fin 220_1 to form the N-type transistor N1, i.e., the N-type transistor N1 is a single fin transistor.

The gate structure 240_2a is separated from the gate structure 240_2b, and the gate structure 240_2b is separated from the gate structure 240_2c. In some embodiments, the gate structure 240_2b is separated from the gate structures 240_2a and 240_2c by performing the CMG process. In some embodiments, the upper parts of semiconductor fins 220_2 and 225_2 are removed during the CMG process.

It should be noted that among two adjacent semiconductor fins (e.g., the semiconductor fins 225_1 and 225_2 or the semiconductor fins 220_1 and 220_2) in FIG. 3D, only one semiconductor fin is covered by the gate structure. For example, the semiconductor fin 225_1 is covered by the gate structure 240_2a, and the semiconductor fin 220_1 is covered by the gate structure 240_2c. Furthermore, the semiconductor fin 225_1 overlapping the gate structure 240_2a is separated from the semiconductor fin 220_1 overlapping the gate structure 240_2c by the semiconductor fins 225_2 and 220_2 not overlapping any gate structure. In other words, the semiconductor fins 225_2 and 220_2 that close to the interface between the P-type well region PW and the N-type well region are not covered by the gate structure.

FIG. 3E shows a cross-sectional view of the semiconductor structure of the logic cell along line E-E′ of FIG. 2 according to some embodiments of the invention. The gate structure 240_3 extends in the Y-direction and overlaps the semiconductor fins 225_1 and 225_2 to form the P-type transistor P3, i.e., the P-type transistor P3 is a dual-fin transistor. Furthermore, the gate structure 240_3 extends in the Y-direction and overlaps the semiconductor fins 220_1 and 220_2 to form the N-type transistor N3, i.e., the N-type transistor N3 is a dual-fin transistor. In other words, the P-type transistor P3 and the N-type transistor N3 share the gate structure 240_3.

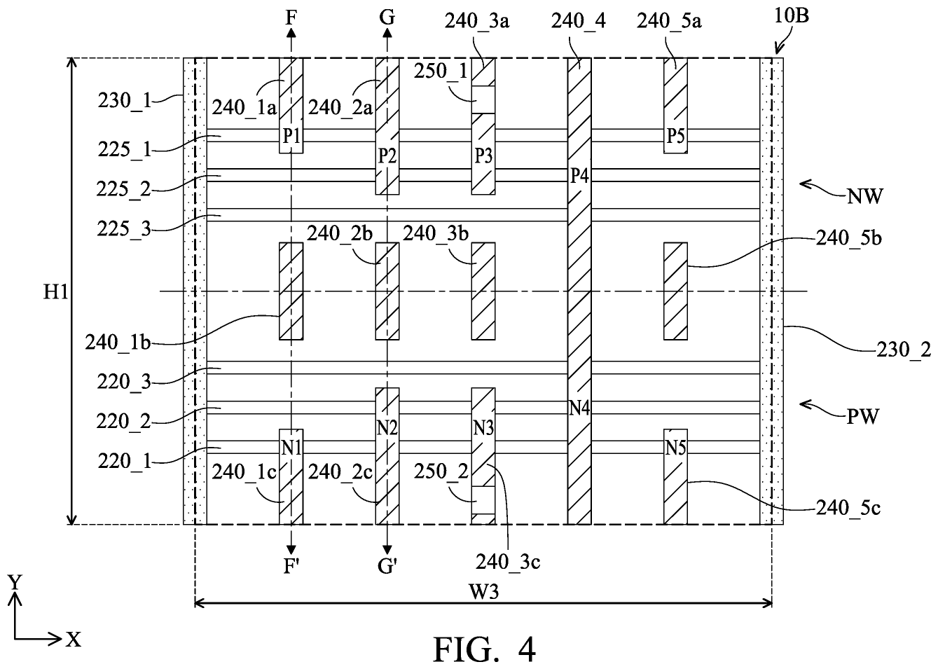

FIG. 4 shows a simplified layout illustrating the logic cell 10B in a row of the cell array 100 of FIG. 1 according to some embodiments of the invention. The logic cell 10B is arranged between a power line (not shown) and a ground line (not shown). The logic cell 10B has a cell height H1 and a cell weight W3. Furthermore, the outer boundaries of the logic cell 10B are illustrated using dashed lines.

In the logic cell 10B, three fins 225_1 through 225_3 extend in the X-direction over the N-type well region NW, and three semiconductor fins 220_1 through 220_3 extend in the X-direction over the P-type well region PW. In some embodiments, the semiconductor fins 220_1 through 220_3 and the semiconductor fins 225_1 through 225_3 are continuous fins shared by the logic cells in the same row of the cell array 100. The non-active dummy gates 230_1 and 230_2 extending in the Y-direction are dummy gates. Furthermore, the non-active dummy gates 230_1 and 230_2 are arranged in the boundary of the logic cell 10B.

In FIG. 4, the logic cell 10B includes the P-type transistors P1 through P5 over the N-type well region NW and the N-type transistors N1 through N5 over the P-type well region PW. The P-type transistors P1 through P5 and the N-type transistors N1 through N5 are configured to perform a specific logic function for the logic cell 10B. It should be noted that the number of transistors in the logic cell 10B is used as an example, and not to limit the disclosure. The logic cell 10B may include more or fewer P-type transistors and more or fewer N-type transistors to perform a specific function.

Over the N-type well region NW in the logic cell 10B, the gate structure 240_1a extending in the Y-direction forms the P-type transistor P1 with an underlying active region formed by the semiconductor fin 225_1. The gate structure 240_2a extending in the Y-direction forms the P-type transistor P2 with an underlying active region formed by the semiconductor fins 225_1 and 225_2. The gate structure 240_3a extending in the Y-direction forms the P-type transistor P3 with an underlying active region formed by the semiconductor fins 225_1 and 225_2. The gate structure 240_4 extending in the Y-direction forms the P-type transistor P4 with an underlying active region formed by the semiconductor fins 225_1 through 225_3. The gate structure 240_5 extending in the Y-direction forms the P-type transistor P5 with an underlying active region formed by the semiconductor fin 225_1.

Over the P-type well region PW in the logic cell 10B, the gate structure 240_1c extending in the Y-direction forms the N-type transistor N1 with an underlying active region formed by the semiconductor fin 220_1. The gate structure 240_2c extending in the Y-direction forms the N-type transistor N2 with an underlying active region formed by the semiconductor fins 220_1 and 220_2. The gate structure 240_3c extending in the Y-direction forms the N-type transistor N3 with an underlying active region formed by the semiconductor fins 220_1 and 220_2. The gate structure 240_4 extending in the Y-direction forms the N-type transistor N4 with an underlying active region formed by the semiconductor fins 220_1 through 220_3. The gate structure 240_5 extending in the Y-direction forms the N-type transistor N5 with an underlying active region formed by the semiconductor fin 220_1.

In the logic cell 10B, the gate structures 240_1a, 240_1b and 240_1c are aligned in the Y-direction, i.e., the gate structures 240_1a, 240_1b and 240_1c are arranged on the same line. Similarly, the gate structures 240_2a, 240_2b and 240_2c are aligned in the Y-direction, the gate structures 240_3a, 240_3b and 240_3c are aligned in the Y-direction, and the gate structures 240_5a, 240_5b and 240_5c are aligned in the Y-direction. The gate structures 240_1b, 240_2b, 240_3b and 240_5b are disposed between the semiconductor fins 220_3 and 225_3 and across an interface between the N-type well region NW and the P-type well region PW.

Taking the gate structures 240_1a, 240_1b and 240_1c as an example, one end of the gate structure 240_1a is formed between the semiconductor fins 225_1 and 225_2, and one end of the gate structure 240_1c is formed between the semiconductor fins 220_1 and 220_2. In some embodiments, the gate structures 240_1a, 240_1b and 240_1c are formed by the RMG process. The replacement metal gate process is performed to create a sacrificial or dummy gate during fabrication, and then later replacing the dummy gate with a metal gate structure. In some embodiments, the gate structures 240_1a, 240_1b and 240_1c are formed by performing the CMG process on a gate structure.

Furthermore, the gate structures 240_2a, 240_2b and 240_2c are aligned in the Y-direction, i.e., the gate structures 240_2a, 240_2b and 240_2c are arranged on the same line. Similarly, the gate structures 240_2a, 240_2b and 240_2c are aligned in the Y-direction, the gate structures 240_3a, 240_3b and 240_3c are aligned in the Y-direction, and the gate structures 240_5a, 240_5b and 240_5c are aligned in the Y-direction. The gate structures 240_1b, 240_2b, 240_3b and 240_5b are disposed between the semiconductor fins 220_3 and 225_3 and across an interface between the N-type well region NW and the P-type well region PW.

Taking the gate structures 240_2a, 240_2b and 240_2c as an example, one end of the gate structure 240_2a is formed between the semiconductor fins 225_2 and 225_3, and one end of the gate structure 240_2c is formed between the semiconductor fins 220_2 and 220_3. Similar to the logic cells 10A_1 and 10A_2, the gate structures in the logic cell 10B have the symmetry layout configuration, e.g., the gate structure layout is mirrored along the interface between the N-type well region NW and the P-type well region PW.

In FIG. 4, the single-fin transistors and the multi-fin transistors are formed in the logic cell 10B. The multi-fin transistors are used for performance (e.g., speed), and the single-fin transistors are used for low power. Therefore, compared with the traditional performance cell array formed by the logic cells with the multi-fin transistors or the traditional low power cell array formed by the logic cells with the single-fin transistors, the logic cell 100 including the logic cell 10B is capable of satisfying low power and high-performance (off-state leakage current requirements).

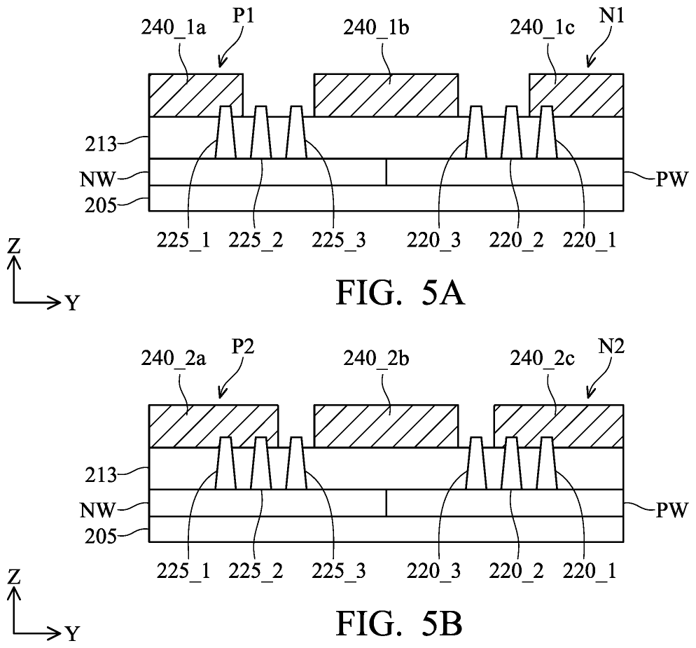

FIG. 5A shows a cross-sectional view of the semiconductor structure of the logic cell along line F-F′ of FIG. 4 according to some embodiments of the invention. The N-type well region NW and the P-type well region PW are formed over the semiconductor substrate 205. The semiconductor fins 225_1 through 225_3 are formed over the N-type well region NW, and the semiconductor fins 220_1 through 220_3 are formed over the P-type well region PW. In the logic cell 10B, the number of semiconductor fins 225_1 through 225_3 over the N-type well region NW is equal to the number of semiconductor fins 220_1 through 220_3 over the P-type well region PW.

The gate structure 240_1a extends in the Y-direction and overlaps the semiconductor fin 225_1 to form the P-type transistor P1, i.e., the P-type transistor P1 is a single fin transistor. The gate structure 240_1b extends in the Y-direction and overlaps the interface between the N-type well region NW and the P-type well region PW. The gate structure 240_1c extends in the Y-direction and overlaps the semiconductor fin 220_1 to form the N-type transistor N1, i.e., the N-type transistor N1 is a single fin transistor. The gate structure 240_1b is separated from the gate structures 240_1a and 240_1c.

Among three adjacent semiconductor fins (e.g., the semiconductor fins 225_1 through 225_3 or the semiconductor fins 220_1 through 220_3) in FIG. 5A, only one semiconductor fin is covered by the gate structure. For example, the semiconductor fin 225_1 is covered by the gate structure 240_1a, and the semiconductor fin 220_1 is covered by the gate structure 240_1c. Furthermore, the semiconductor fin 225_1 overlapping the gate structure 240_1a is separated from the semiconductor fin 220_1 overlapping the gate structure 240_1c by the semiconductor fins 225_2 and 225_3 and the semiconductor fins 220_2 and 220_3 not overlapping any gate structure. In other words, the semiconductor fins 225_2 and 225_3 and the semiconductor fins 220_2 and 220_3 close to the interface between the P-type well region PW and the N-type well region are not covered by the gate structure.

FIG. 5B shows a cross-sectional view of the semiconductor structure of the logic cell along line G-G′ of FIG. 4 according to some embodiments of the invention. The gate structure 240_2a extends in the Y-direction and overlaps the semiconductor fins 225_1 and 225_2 to form the P-type transistor P2, i.e., the P-type transistor P2 is a dual-fin transistor. The gate structure 240_2b extends in the Y-direction and overlaps the interface between the N-type well region NW and the P-type well region PW. The gate structure 240_2c extends in the Y-direction and overlaps the semiconductor fins 220_1 and 220_2 to form the N-type transistor N2, i.e., the N-type transistor N2 is a dual-fin transistor. The gate structure 240_2b is separated from the gate structures 240_2a and 240_2c.

Among three adjacent semiconductor fins (e.g., the semiconductor fins 225_1 through 225_3 or the semiconductor fins 220_1 through 220_3) in FIG. 5B, only two adjacent semiconductor fins are covered by the gate structure. For example, the semiconductor fins 225_1 and 225_2 are covered by the gate structure 240_2a, and the semiconductor fins 220_1 and 220_2 are covered by the gate structure 240_2c. Furthermore, the semiconductor fins 225_1 and 225_2 overlapping the gate structure 240_1a are separated from the semiconductor fins 220_1 and 220_2 overlapping the gate structure 240_2c by the semiconductor fins 225_3 and 220_3 not overlapping any gate structure. In other words, the semiconductor fins 225_3 and 220_3 close to the interface between the P-type well region PW and the N-type well region are not covered by the gate structure.

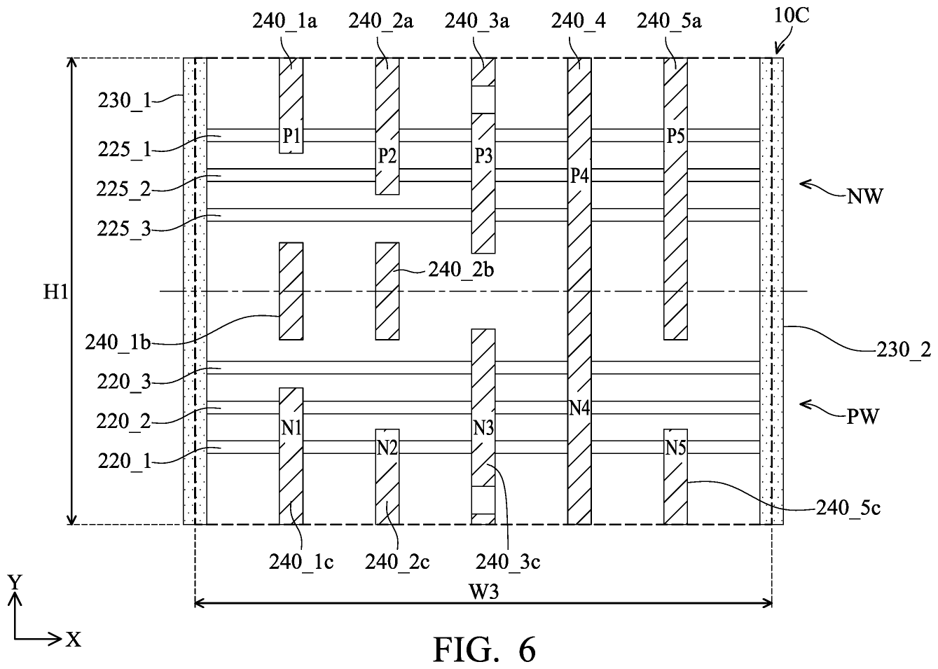

FIG. 6 shows a simplified layout illustrating a logic cell 10C in a row of the cell array 100 of FIG. 1 according to some embodiments of the invention. The logic cell 10C is arranged between a power line (not shown) and a ground line (not shown). The logic cell 10C has a cell height H1 and a cell weight W3. Furthermore, the outer boundaries of the logic cell 10C illustrated using dashed lines.

In the logic cell 10C, three fins 225_1 through 225_3 extend in the X-direction over the N-type well region NW, and three semiconductor fins 220_1 through 220_3 extend in the X-direction over the P-type well region PW. In the logic cell 10C, the number of semiconductor fins 225_1 through 225_3 over the N-type well region NW is equal to the number of semiconductor fins 220_1 through 220_3 over the P-type well region PW. In some embodiments, the semiconductor fins 220_1 through 220_3 and the semiconductor fins 225_1 through 225_3 are continuous fins shared by the logic cells in the same row of the cell array 100. The non-active dummy gates 230_1 and 230_2 extending in the Y-direction are dummy gates. Furthermore, the non-active dummy gates 230_1 and 230_2 are arranged in the boundary of the logic cell 10C.

In FIG. 6, the logic cell 10C includes the P-type transistors P1 through P5 over the N-type well region NW and the N-type transistors N1 through N5 over the P-type well region PW. The P-type transistors P1 through P5 and the N-type transistors N1 through N5 are configured to perform a specific logic function for the logic cell 10C. It should be noted that the number of transistors in the logic cell 10C is used as an example, and not to limit the disclosure. The logic cell 10C may include more or fewer P-type transistors and more or fewer N-type transistors to perform a specific function. In some embodiments, the logic cell 10C of FIG. 6 and the logic cell 10B of FIG. 4 have the same specific logic function for different power consumption and different speed.

Over the N-type well region NW in the logic cell 10C, the gate structure 240_1aextending in the Y-direction forms the P-type transistor P1 with an underlying active region formed by the semiconductor fin 225_1. The gate structure 240_2a extending in the Y-direction forms the P-type transistor P2 with an underlying active region formed by the semiconductor fins 225_1 and 225_2. The gate structure 240_3a extending in the Y-direction forms the P-type transistor P3 with an underlying active region formed by the semiconductor fins 225_1 through 225_3. The gate structure 240_4 extending in the Y-direction forms the P-type transistor P4 with an underlying active region formed by the semiconductor fins 225_1 through 225_3. The gate structure 240_5a extending in the Y-direction forms the P-type transistor P5 with an underlying active region formed by the semiconductor fins 225_1 through 225_3.

Over the P-type well region PW in the logic cell 10C, the gate structure 240_1c extending in the Y-direction forms the N-type transistor N1 with an underlying active region formed by the semiconductor fins 220_1 and 220_2. The gate structure 240_2c extending in the Y-direction forms the N-type transistor N2 with an underlying active region formed by the semiconductor fin 220_1. The gate structure 240_3c extending in the Y-direction forms the N-type transistor N3 with an underlying active region formed by the semiconductor fins 220_1 through 220_3. The gate structure 240_4 extending in the Y-direction forms the N-type transistor N4 with an underlying active region formed by the semiconductor fins 220_1 through 220_3. The gate structure 240_5 extending in the Y-direction forms the N-type transistor N5 with an underlying active region formed by the semiconductor fin 220_1.

Compared with the logic cell 10B in FIG. 4 that has the gate structure with the symmetry layout configuration, the gate structures have the asymmetry layout configuration in the logic cell 10C. For example, one end of the gate structure 240_1a is formed between the semiconductor fins 225_1 and 225_2, and one end of the gate structure 240_1c is formed between the semiconductor fins 220_2 and 220_3. In other words, the N-type transistor N1 is a dual-fin transistor and the P-type transistor P1 is a single fin transistor. Moreover, one end of the gate structure 240_2a is formed between the semiconductor fins 225_2 and 225_3, and one end of the gate structure 240_2c is formed between the semiconductor fins 220_1 and 220_2. In other words, the N-type transistor N2 is a single-fin transistor and the P-type transistor P2 is a dual-fin transistor. Furthermore, one end of the gate structure 240_5a is formed between the semiconductor fins 225_3 and 220_3, and one end of the gate structure 240_5c is formed between the semiconductor fins 220_1 and 220_2. In other words, the N-type transistor N5 is a single-fin transistor and the P-type transistor P5 is a triple-fin transistor.

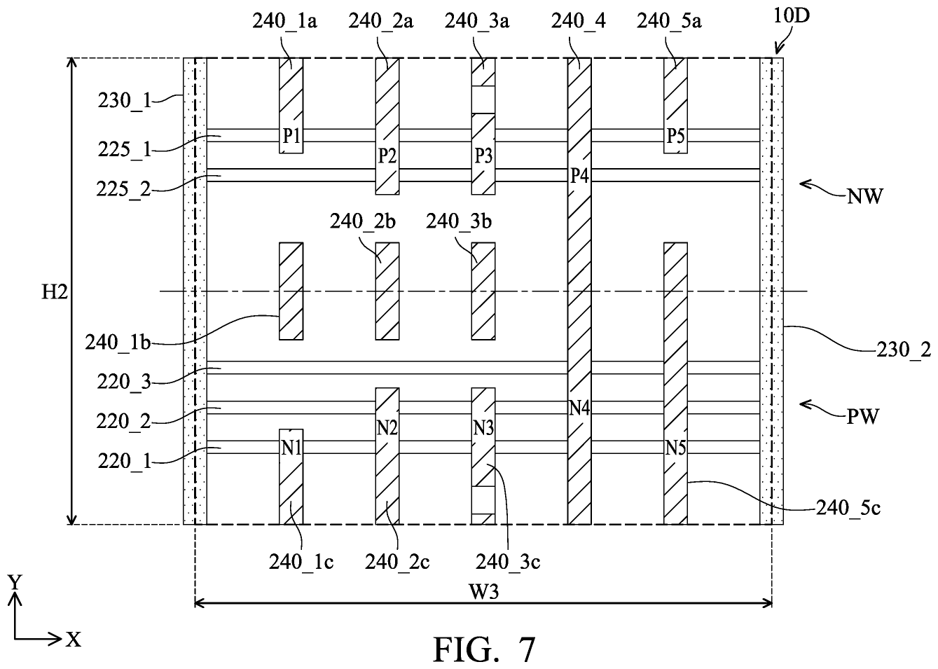

FIG. 7 shows a simplified layout illustrating a logic cell 10D in a row of the cell array 100 of FIG. 1 according to some embodiments of the invention. The logic cell 10D is arranged between a power line (not shown) and a ground line (not shown). The logic cell 10D has a cell height H1 and a cell weight W3. Furthermore, the outer boundaries of the logic cell 10D are illustrated using dashed lines.

In the logic cell 10D, two fins 225_1 and 225_2 extend in the X-direction over the N-type well region NW, and three semiconductor fins 220_1 through 220_3 extend in the X-direction over the P-type well region PW. In the logic cell 10D, the number of semiconductor fins 225_1 and 225_2 over the N-type well region NW is equal to the number of semiconductor fins 220_1 through 220_3 over the P-type well region PW. In some embodiments, the semiconductor fins 220_1 and 220_2 and the semiconductor fins 225_1 through 225_3 are continuous fins shared by the logic cells in the same row of the cell array 100. The non-active dummy gates 230_1 and 230_2 extending in the Y-direction are dummy gates. In other words, the non-active dummy gates 230_1 and 230_2 are arranged in the boundary of the logic cell 10D. Compared with the logic cell 10B with the symmetry layout configuration in FIG. 4, the gate structures have the asymmetry layout configuration in the logic cell 10D since the number of fins (e.g., the semiconductor fins 225_1 and 225_2) over the N-type well region NW is different than the number of fins (e.g., the semiconductor fins 220_1 through 220_3) over the P-type well region PW.

In FIG. 7, the logic cell 10D includes the P-type transistors P1 through P5 over the N-type well region NW and the N-type transistors N1 through N5 over the P-type well region PW. The P-type transistors P1 through P5 and the N-type transistors N1 through N5 are configured to perform a specific logic function for the logic cell 10D. It should be noted that the number of transistors in the logic cell 10D is used as an example, and not to limit the disclosure. The logic cell 10D may include more or fewer P-type transistors and more or fewer N-type transistors to perform a specific function. In some embodiments, the logic cell 10D of FIG. 7 and the logic cell 10B of FIG. 4 have the same specific logic function for different power consumption and different speed.

Over the N-type well region NW in the logic cell 10D, the gate structure 240_1a extending in the Y-direction forms the P-type transistor P1 with an underlying active region formed by the semiconductor fin 225_1. The gate structure 240_2a extending in the Y-direction forms the P-type transistor P2 with an underlying active region formed by the semiconductor fins 225_1 and 225_2. The gate structure 240_3a extending in the Y-direction forms the P-type transistor P3 with an underlying active region formed by the semiconductor fins 225_1 and 225_2. The gate structure 240_4 extending in the Y-direction forms the P-type transistor P4 with an underlying active region formed by the semiconductor fins 225_1 and 225_2. The gate structure 240_5 extending in the Y-direction forms the P-type transistor P5 with an underlying active region formed by the semiconductor fin 225_1.

Over the P-type well region PW in the logic cell 10D, the gate structure 240_1c extending in the Y-direction forms the N-type transistor N1 with an underlying active region formed by the semiconductor fin 220_1. The gate structure 240_2c extending in the Y-direction forms the N-type transistor N2 with an underlying active region formed by the semiconductor fins 220_1 and 220_2. The gate structure 240_3c extending in the Y-direction forms the N-type transistor N3 with an underlying active region formed by the semiconductor fins 220_1 and 220_2. The gate structure 240_4 extending in the Y-direction forms the N-type transistor N4 with an underlying active region formed by the semiconductor fins 220_1 through 220_3. The gate structure 240_5 extending in the Y-direction forms the N-type transistor N5 with an underlying active region formed by the semiconductor fins 220_1 through 220_3.

According to the embodiments, high speed and lower power in the same row of the cell array 100 are achieved by removing metal gate of the multi-fin FinFET structure in the logic cells (e.g., the logic cells 10A_1, 10A_2, 10B, 10C or 10D) to provide less fin transistors (e.g., single fin transistor or dual-fin transistor). In some embodiments, each row of the cell array 100 may include individual number of fins for P-type and N-type transistors. In some embodiments, the number of fins configured to form the P-type transistors is different form the number of fins configured to form the N-type transistors in the same row of the cell array. In some embodiments, the semiconductor fins are continuous fins in the rows of the cell array. In some embodiments, the total number of semiconductor fins in each row of the cell array 100 is different, and the rows of the cell array 100 may have the same cell height (e.g., the cell height H1). In some embodiments, the total number of semiconductor fins in each row of the cell array 100 is different, and the rows of the cell array 100 may have individual cell heights. For example, in the cell array 100, a first row including less semiconductor fins has a first cell height and a second row including more semiconductor fins has a second cell height that is greater than the first cell height. In some embodiments, the total number of semiconductor fins in each row of the cell array 100 is the same, and the rows of the cell array 100 have the same cell height (e.g., the cell height H1).

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor structure, comprising:
a logic cell, comprising:
a first transistor, comprising a first gate structure extending in a first direction and overlapping a first semiconductor fin; and
a second transistor, comprising a second gate structure extending in the first direction and overlapping the first semiconductor fin and a second semiconductor fin,
wherein the first and second semiconductor fins extend in a second direction that is perpendicular to the first direction,
wherein the first and second transistors share a source/drain region, and one end of the first gate structure is formed between the first and second semiconductor fins.

2. The semiconductor structure as claimed in claim 1, wherein the first and second transistors have the same conductivity type.

3. The semiconductor structure claimed in claim 1, wherein the first and second semiconductor fins have the same length in the logic cell.

4. The semiconductor structure claimed in claim 1, wherein the logic cell further comprises:
a third transistor, comprising the second gate structure extending in the first direction and overlapping a third semiconductor fin,
wherein the third semiconductor fin is parallel to the first and second semiconductor fins, and the second and third transistors have different conductivity types.

5. A semiconductor structure, comprising:
a cell array, comprising a plurality of first logic cells,
wherein P-type transistors of the first logic cells disposed in a first row of the cell array share a plurality of first continuous fins, and N-type transistors of the first logic cells disposed in the first row of the cell array share a plurality of second continuous fins,
wherein the number of the first continuous fins is different from the number of the second continuous fins in the first row of the cell array.

6. The semiconductor structure claimed in claim 5, wherein the first continuous fins and the second continuous fins have the same length.

7. The semiconductor structure claimed in claim 5, wherein one of the first logic cells in the first row of the cell array comprises a single fin P-type transistor, and the single fin P-type transistor comprises a gate structure overlapping one of the first continuous fins.

8. The semiconductor structure claimed in claim 5, wherein one of the first logic cells in the first row of the cell array comprises a single fin N-type transistor, and the single fin N-type transistor comprises a gate structure overlapping one of the second continuous fins.

9. The semiconductor structure claimed in claim 5, wherein one of the first logic cells in the first row of the cell array comprises a dual-fin P-type transistor, and the dual-fin P-type transistor comprises a gate structure overlapping two adjacent ones of the first continuous fins.

10. The semiconductor structure claimed in claim 5, wherein one of the first logic cells in the first row of the cell array comprises a dual-fin N-type transistor, and the dual-fin N-type transistor comprises a gate structure overlapping two adjacent ones of the second continuous fins.

11. The semiconductor structure claimed in claim 5, wherein one of the first logic cells in the first row of the cell array comprises a multi-fin P-type transistor and a multi-fin N-type transistor that share a gate structure, and the gate structure overlaps all of the first and second continuous fins.

12. The semiconductor structure claimed in claim 5, wherein the cell array further comprises:
a plurality of second logic cells,
wherein P-type transistors of the second logic cells disposed in a second row of the cell array share a plurality of third continuous fins, and N-type transistors of the second logic cells disposed in the second row of the cell array share a plurality of fourth continuous fins,
wherein the number of the third continuous fins is equal to the number of the fourth continuous fins in the second row of the cell array.

13. A semiconductor structure, comprising:
a plurality of logic cells formed in a cell array,
wherein P-type transistors of the logic cells disposed in a first row of the cell array share a plurality of first semiconductor fins extending in a first direction, and N-type transistors of the logic cells disposed in the first row of the cell array share a plurality of second semiconductor fins extending in the first direction,
wherein a first logic cell in the first row of the cell array comprises a first P-type transistor and a first N-type transistor,
wherein the number of the first semiconductor fins overlapping a first gate structure of the first P-type transistor is different from the number of the second semiconductor fins overlapping a second gate structure of the first N-type transistor,
wherein the first and second gate structures extend in a second direction that is perpendicular to the first direction, and the first and second gate structures are aligned in the second direction.

14. The semiconductor structure claimed in claim 13, wherein the first logic cell further comprises a second P-type transistor and a second N-type transistor, wherein the number of the first semiconductor fins overlapping a gate structure of the second P-type transistor is equal to the number of the second semiconductor fins overlapping a gate structure of the second N-type transistor, wherein the gate structures of the second P-type and N-type transistors are aligned in the second direction.

15. The semiconductor structure claimed in claim 13, wherein the first logic cell further comprises a third P-type transistor and a third N-type transistor, and the third P-type transistor and the third N-type transistor share a common electrode, and the common electrode extends in the second direction and overlaps all of the first and second semiconductor fins.

16. The semiconductor structure claimed in claim 13, wherein the number of the first semiconductor fins is equal to the number of the second semiconductor fins.

17. The semiconductor structure claimed in claim 13, wherein in each row of the cell array, the first semiconductor fins and the second semiconductor fins have the same length.

18. The semiconductor structure claimed in claim 13, wherein a second logic cell in the first row of the cell array comprises a single fin P-type transistor or a single fin N-type transistor, and the single fin P-type transistor comprises a gate structure overlapping one of the first semiconductor fins, and the single fin N-type transistor comprises a gate structure overlapping one of the second semiconductor fins.

19. The semiconductor structure claimed in claim 13, wherein a third logic cell in the first row of the cell array comprises a dual-fin P-type transistor or a dual-fin N-type transistor, and the dual-fin P-type transistor comprises a gate structure overlapping two adjacent ones of the first semiconductor fins, and the dual-fin N-type transistor comprises a gate structure overlapping two adjacent ones of the second semiconductor fins.

20. The semiconductor structure claimed in claim 13, wherein the first semiconductor fins overlapping the first gate structure are separated from the second semiconductor fins overlapping the second gate structure by the first semiconductor fins not overlapping the first gate structure and the second semiconductor fins not overlapping the second gate structure.
